(19) United States
(12) Patent Application Publication
(10) Pub. No.: US 2025/0203915 A1
(43) Pub. Date: Jun. 19, 2025

(54) SEMICONDUCTOR DEVICE AND METHOD FOR MANUFACTURING SEMICONDUCTOR DEVICE

(71) Applicants: HPSP Co., Ltd., Hwaseong-si, Gyeonggi-do (KR); POSTECH Research and Business Development Foundation, Pohang-si, Gyeongsangbuk-do (KR)

(72) Inventors: Hyunsang HWANG, Daegu (KR); Yong Woon KIM, Hwaseong-si (KR); Tae Jung KIM, Hwaseong-si (KR)

(73) Assignees: HPSP Co., Ltd., Hwaseong-si, Gyeonggi-do (KR); POSTECH Research and Business Development Foundation, Pohang-si, Gyeongsangbuk-do (KR)

(21) Appl. No.: 18/851,913

(22) PCT Filed: Mar. 29, 2023
(86) PCT No.: PCT/KR2023/004169

§ 371 Date: Sep. 27, 2024

(30) Foreign Application Priority Data
Mar. 29, 2022 (KR) 10-2022-0038932

(51) Int. Cl. H10D 30/00; H10D 30/01; H10D 30/43; H10D 62/10; H10D 64/01; H10D 64/66

(52) U.S. Cl. CPC H10D 30/502; H10D 30/014; H10D 30/0191; H10D 30/43; H10D 62/102; H10D 62/121; H10D 64/017; H10D 64/021; H10D 64/675

(57) ABSTRACT

The present invention relates to a semiconductor device and a method for manufacturing a semiconductor device. In one embodiment, a method for manufacturing a semiconductor device may comprise the steps of: growing a stack layer by alternately stacking sacrificial layers and channel regions on a substrate; forming a sacrificial poly gate on the stack layer; forming inner spacers and side spacers on side surfaces of the sacrificial layers and side surfaces of the sacrificial poly gate; and heat treating the inner spacers or the side spacers in a chamber set to a predetermined process pressure and a predetermined process temperature.

### FIELD

The present disclosure relates to a semiconductor device and a method for manufacturing the semiconductor device.

### DESCRIPTION OF RELATED ART

A semiconductor device is a component which is mainly used in electronic circuits or similar devices using an electrical conduction characteristic of a semiconductor. The semiconductors may be classified into a memory semiconductor and a non-memory semiconductor. The memory semiconductor may be classified into a volatile memory such as DRAM or SRAM and a non-volatile memory such as Mask ROM, EP ROM, EEP ROM, and flash memory.

A new process for making a size of a semiconductor device to be smaller and a semiconductor device having a new structure according to the new process have been developed. A representative example of thereof may be a gate-all-around (GAA) process. According to the gate-all-around process, the gate and the channel are in contact with each other on four sides, such that the current flow can be precisely controlled, so that limitation of a conventional semiconductor device may be overcome.

Recently, a multi-bridge channel FET (MBCFET) as a new structure for solving the disadvantages of the gate-all-around structure is disclosed. According to the structure of the MBCFET, a channel area is formed in a form of a nanosheet, such that an substantial contact area between the gate and the channel is increased, and accordingly, an amount of current flowing between the gate and the channel increases.

### DISCLOSURE

### Technical Purpose

A purpose of the present invention is to improve film quality of an inner spacer or a side spacer included in a semiconductor device including a nanosheet.

The purpose of the present disclosure is not limited to the above-mentioned purpose, and other purposes and advantages of the present disclosure, which are not mentioned, will be more clearly understood based on embodiments of the present disclosure as described below. In addition, the purposes and advantages of the present disclosure may be realized based on components and combinations thereof described in the Claims.

### Technical Solution

A method for manufacturing a semiconductor device according to one embodiment may include growing a stack layer on a substrate, wherein the stack layer includes sacrificial layers and channel areas stacked alternately on top of each other; forming a sacrificial poly gate on the stack layer; forming an inner spacer and a side spacer on a side surface of the sacrificial layer and a side surface of the sacrificial poly gate, respectively; and performing heat treatment on the inner spacer or the side spacer in a chamber having a pressure set to a predetermined process pressure and a temperature set to a predetermined process temperature.

A semiconductor device according to one embodiment may include a substrate; a channel area including a plurality of nanosheets stacked on the substrate; a gate electrode disposed so as to contact at least one surface of the channel area; a source area and a drain area disposed on both opposing sides of the channel area, respectively; a side spacer disposed on a side surface of the gate electrode; and an inner spacer disposed on a side surface of the gate electrode, wherein a heat treatment may be performed on the side spacer or the inner spacer in a chamber having a pressure set to a predetermined process pressure and a temperature set to a predetermined process temperature such that an oxide film layer is formed on an outer surface of the side spacer or the inner spacer.

### Technical Effect

According to the method for manufacturing the semiconductor device according to some embodiments, a film quality of the inner spacer or the side spacer of the semiconductor device may be improved. That is, since a thickness of the inner spacer or the side spacer becomes uniform and stability thereof is improved, insulating properties of the inner spacer or the side spacer may be improved. Accordingly, parasitic capacitance between the gate electrode and each of the source and drain areas may be reduced, such that electrical characteristics and reliability of the semiconductor device may be improved.

### BRIEF DESCRIPTION OF THE DRAWINGS

FIG. 1 is a cross-sectional view illustrating a structure of a semiconductor device according to an embodiment.

FIGS. 2A to 2G illustrate a process of manufacturing a semiconductor device according to an embodiment.

FIG. 3 is a flowchart for illustrating a method for manufacturing a semiconductor device according to an embodiment.

FIGS. 4A to 4E are cross-sectional views illustrating for a method for fabricating a semiconductor device according to another embodiment.

FIG. 5 is a flowchart for illustrating a method for manufacturing a semiconductor device according to still another embodiment.

FIG. 6 is a graph illustrating a leakage current value measured when a voltage is applied to a semiconductor device manufactured according to the related art and a semiconductor device manufactured according to embodiments of the present disclosure.

### DETAILED DESCRIPTIONS

The foregoing purposes, features, and advantages will be described in detail with reference to the accompanying drawings, and thus, those skilled in the art to which the present disclosure pertains may easily implement the embodiments of the present disclosure. In the following descriptions of the present disclosure, a detailed description of known functions and components as incorporated herein will be omitted when it may make the gist of the present disclosure rather unclear. Hereinafter, preferred embodiments of the present disclosure will be described in detail with reference to the accompanying drawings. Like reference numerals in the drawings denote the same or similar elements.

As used herein, the term “nanosheet” refers to a conductive structure having a cross-section that is substantially perpendicular to a direction in which a current flows through the nanosheet. Further, one of the Cartesian cross-sectional dimensions within the nanosheet is significantly smaller than the other Cartesian cross-sectional dimensions. For example, the nanosheet may include a conductive structure having a cross-sectional area in which one of the Cartesian cross-sectional dimensions ranges from several nm to about 20 nm and each of the other Cartesian cross-sectional dimensions ranges from about 15 nm to about 70 nm.

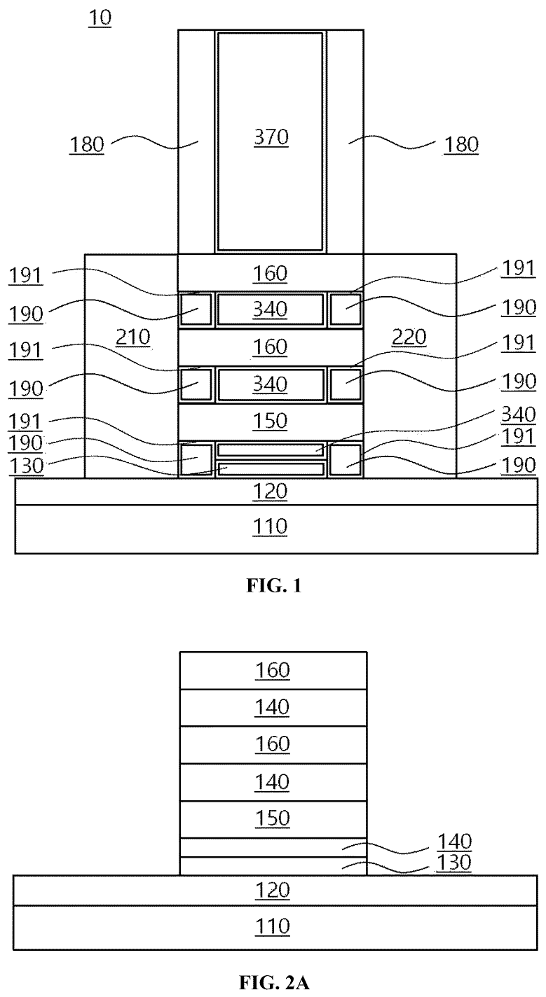

FIG. 1 is a cross-sectional view illustrating a structure of a semiconductor device according to an embodiment.

Referring to FIG. 1, a semiconductor device 10 according to an embodiment may include a substrate 110 and 120, a source area 210, a drain area 220, gate electrodes 340 and 370, channel areas 150 and 160, a side spacer 180, and an inner spacer 190.

The base substrate layer 110 may be a single crystal substrate. The base substrate layer 110 may include a single crystal semiconductor layer on at least one surface thereof. The single crystal semiconductor layer may be made of any one selected from the group consisting of Si, Ge, SiGe, GeSn, InSb, GaAs, GaP, InAlAs, InGaAs, GaSbP, GaAsSb and InP. However, the present disclosure is not limited thereto.

The buffer substrate layer 120 may be formed on the base substrate layer 110 in an epitaxial growth manner. The buffer substrate layer 120 may be formed by doping the base substrate layer 110 with impurities of a material different from that of the base substrate layer 110.

The buffer substrate layer 120 may have a lattice constant different from that of the base substrate layer 110 to minimize lattice stress. In some embodiments, the lattice constant and the crystal structure of the buffer substrate layer 120 may be substantially the same as the lattice constant and the crystal structure of the base substrate layer 110.

The buffer substrate layer 120 may include a stack of layer having different lattice constants. For example, the buffer substrate layer 120 may be configured such that the lattice constant may increase as the buffer substrate layer extends from a lower layer to a higher layer.

The source area 210 and the drain area 220 may be respectively disposed on both opposing ends of the channel areas 150 and 160.

The gate electrodes 340 and 370 may control the flow of current passing through the channel area 150 and 160. The gate electrodes 340 and 370 may be disposed between the source area 210 and the drain area 220. The gate electrodes 340 and 370 may surround upper surfaces, lower surfaces, and side surfaces of the channel areas 150 and 160, that is, the base nanosheet 150 and the nanosheet 160, that is, may be in contact with upper surfaces, lower surfaces, and side surfaces of the channel areas 150 and 160, that is, the base nanosheet 150 and the nanosheet 160.

The base gate insulating film 130 may prevent parasitic coupling of the substrate 110 and 120 by the gate electrodes 340 and 370. The base gate insulating film 130 may prevent an undesirable conductive channel from being formed in the substrate 110 and 120 when the semiconductor device 10 is conductive. In FIG. 1, the base gate insulating film 130 may be disposed under the lowermost gate electrode 340. In some embodiments, the base gate insulating film 130 may be omitted.

The channel areas 150 and 160 may include the base nanosheet 150 as the lowermost nanosheet and at least one nanosheet 160 stacked on top of the base nanosheet 150. In an embodiment, the channel areas 150 and 160 may be spaced apart from each other in the vertical direction. The channel areas 150 and 160 and the gate electrodes 340 and 370 may be stacked and may be arranged alternately with each other vertically. The channel areas 150 and 160 may be disposed between the source area 210 and the drain area 220 in a horizontal direction. The number of nanosheets 160 included in the channel areas 150 and 160 may vary depending on embodiments.

Each of the channel areas 150 and 160 may be defined as a conductive structure having a cross-section perpendicular to a direction in which a current flows. Each of the base nanosheet 150 and the nanosheet 160 may be made of a conductive impurity-doped material. For example, each of the base nanosheet 150 and the nanosheet 160 may include Si, SiGe, Ge, and a Group III-IV semiconductor material such as InGaAs.

The base nanosheet 150 and the nanosheet 160 may be spaced apart from each other in the vertical direction. Each of the base nanosheet 150 and the nanoshect 160 may have a plate shape. A horizontal length of each of the base nanosheet 150 and the nanosheet 160 may be greater than a vertical thickness of each of the base nanosheet 150 and the nanosheet 160.

The inner spacer 190 may reduce parasitic capacitance between the gate electrode 340 and each of the source area 210 and the drain area 220.

The inner spacer 190 may be disposed on a side surface of the gate electrode 340. Accordingly, the source area 210 and the drain area 220 may be insulated from the gate electrode 340. The inner spacer 190 may be in contact with the channel areas 150 and 160.

An oxide film layer 191 may be formed on an outer surface of the inner spacer 190. In an embodiment, heat treatment may be performed on the outer surface of the inner spacer 190 such that the outer surface of the inner spacer 190 may be oxidized to form the oxide film layer 191. The oxide film layer 191 may improve the film quality of the inner spacer 190. Due to the formation of the oxide film layer 191, a defect of the inner spacer 190 may be reduced and the quality of the inner spacer 190 may be improved.

The side spacer 180 may be formed to surround a portion or an entirety of a side surface of the gate electrode 370. The side spacer 180 may insulate the source area 210 and the drain area 220 from the gate electrode 370. In an embodiment, a heat treatment may be performed on the side spacer 180 to form an oxide coating layer on the outer surface of the side spacer 180. The oxide film layer may improve the film quality of the side spacer 180. Due to the formation of the oxide coating layer, defects of the side spacer 180 may be reduced, and the quality of the side spacer 180 may be improved.

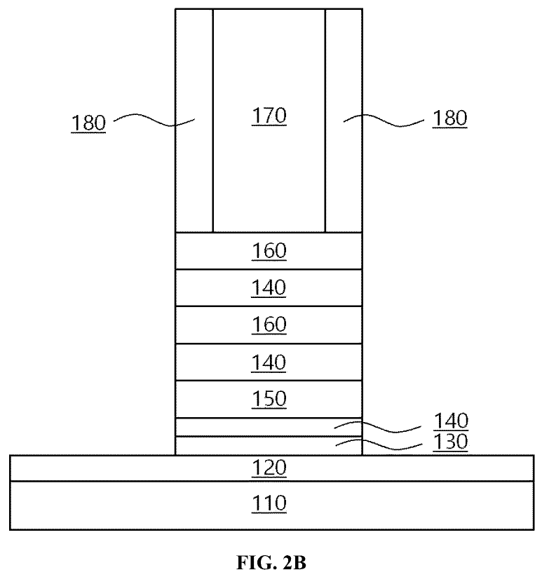

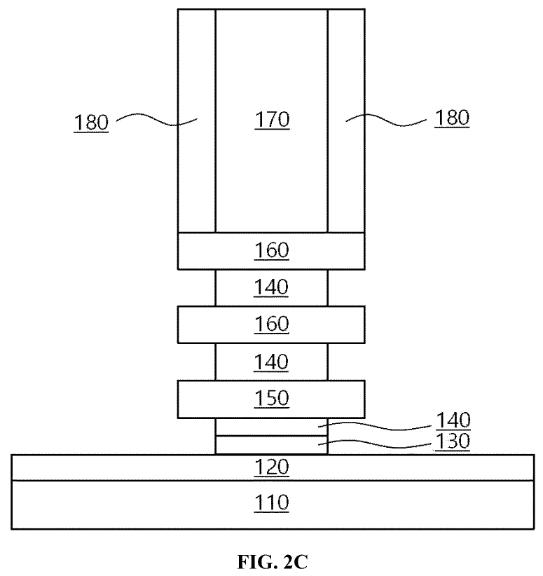

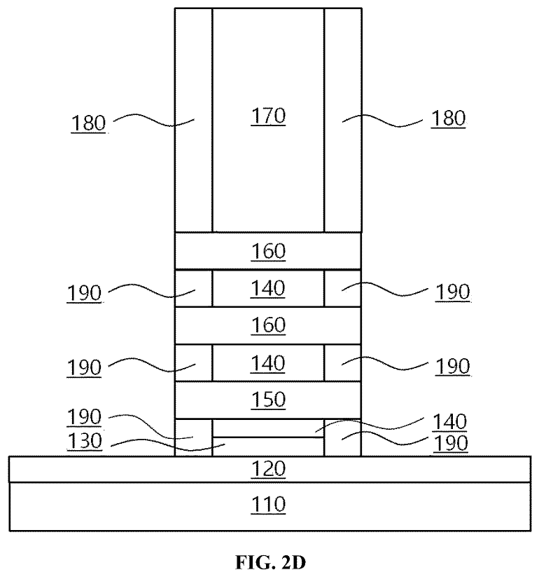

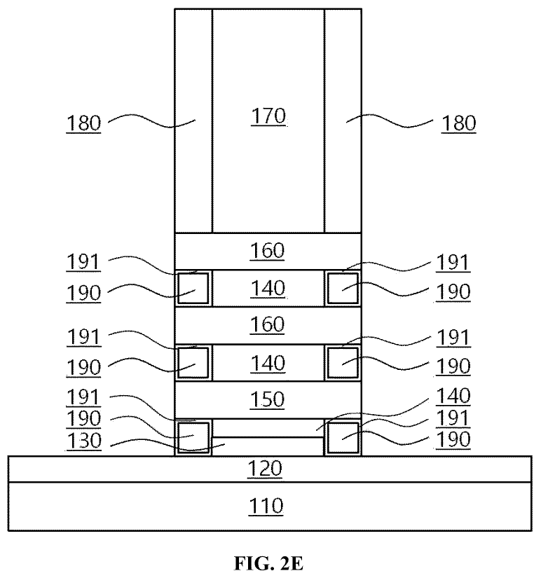

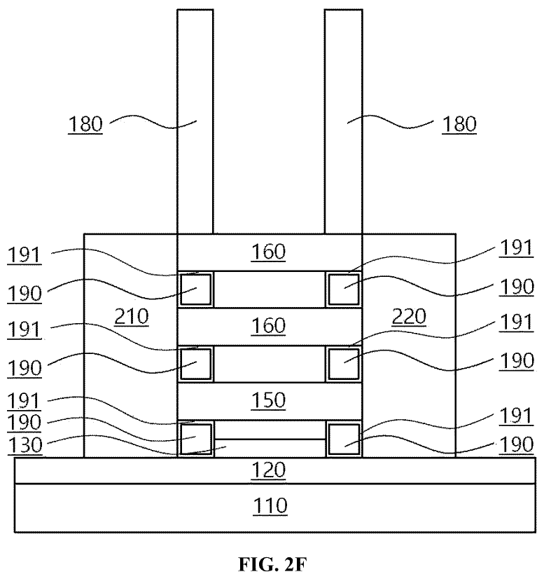

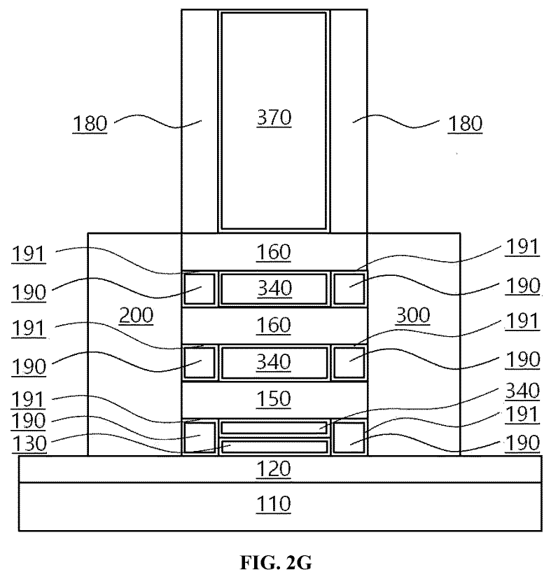

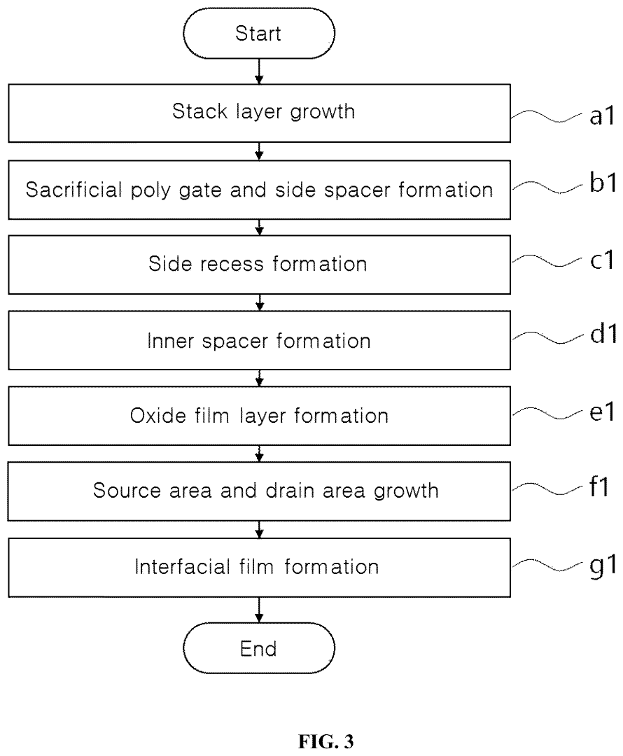

FIGS. 2A to 2G illustrate a process of manufacturing a semiconductor device according to an embodiment. FIG. 3 is a flowchart for illustrating a method for manufacturing a semiconductor device according to an embodiment.

Referring to FIG. 3, a method for manufacturing a semiconductor device according to an embodiment may include a stack layer growth step al, a sacrificial poly gate and side spacer formation step b1, a side recess formation step c1, an inner spacer formation step d1, and an oxide film layer formation step e1. Furthermore, the method for manufacturing the semiconductor device according to an embodiment may further include a step f1 of growing a source area and a drain area, and a step g1 of forming an interfacial film.

Referring to FIG. 2A, in the stack layer growing step a1, the base gate insulating film 130 may be stacked on the substrate 110 and 120. In some embodiments, the base gate insulating film 130 may be omitted. Subsequently, a stack layer, that is, a stack of the sacrificial layers 140 and the channel areas 150 and 160 may be disposed on the base gate insulating film 130 so as to be alternately stacked on top of each other. The sacrificial layers 140 and the channel areas 150 and 160 may be epitaxially formed.

In an embodiment, the sacrificial layer 140 may include SiGe and each of the channel areas 150 and 160 may include Si.

Referring to FIG. 2B, in the step b1 of forming of the sacrificial poly gate and the side spacer, each of a sacrificial poly gate 170 and the side spacer 180 may be formed on the stack layer, that is, a stack of the sacrificial layers 140 and the channel areas 150 and 160.

The sacrificial poly gate 170 may include silicon, for example, poly silicon. The side spacer 180 may include a dielectric material, for example, silicon nitride. The side spacer 180 may include a low dielectric material (or a low-k material).

Referring to FIG. 2C, in the step c1 of forming the side recess, a side recess may be formed by selectively removing a portion of each of the sacrificial layers 140 and the base gate insulating film 130. In the side recess forming step c1, the portion of each of the sacrificial layers 140 and the base gate insulating film 130 may be removed in a wet etching or dry etching manner, and may be removed in a selective etching manner.

Each of the sacrificial layer 140 and the base gate insulating film 130 may have a relatively higher selective etching rate with respect to the channel areas 150 and 160. Accordingly, when the sacrificial layer 140 and the base gate insulating film 130 are removed, the channel areas 150 and 160 may not be removed.

When a stacking process of the base gate insulating film 130 is omitted in the stack layer growing step a1, only a portion of the sacrificial layer 140 may be selectively removed in the side recess forming step c1.

Referring to FIG. 2D, in the inner spacer formation step d1, the inner spacer 190 may be formed in the side recess formed in the side recess formation step c1. In an embodiment, the inner spacer 190 may be formed in an atomic layer deposition (ALD) scheme. The inner spacer 190 may include a low dielectric material (or a low-k material).

Referring to FIG. 2E, in the oxide film layer formation step el, heat treatment may be performed on the inner spacer 190.

More specifically, in the step e1 of forming of the oxide film layer, the heat treatment may be performed on the inner spacer 190 in a chamber having an internal pressure set to a predetermined process pressure and having an internal temperature set to a predetermined process temperature. In an embodiment, the predetermined process pressure may be determined as a value within 2 atm to 100 atm. In one embodiment, the predetermined process temperature may be determined as value in a range of 200° C. to 600° C.

When the heat treatment is performed in the oxide film layer forming step el, the atmosphere gas may be supplied into the chamber. In one embodiment, the atmosphere gas may be O₂ or H₂O. In one embodiment, a concentration of the atmosphere gas in the chamber may be 100%.

In an embodiment, the heat treatment performed in the formation step e1 of the oxide film layer may be performed in any one environment among wet, dry, or supercritical environment.

Referring to FIG. 2F, in the growth step f1 of the source area and the drain area, the source area 210 and the drain area 220 may be respectively formed on both opposing sides of the stack layer, that is, the stack of the sacrificial layers 140 and the channel areas 150 and 160. Further, in the growth step f1 of the source area and the drain area, each of the sacrificial layer 140 and the sacrificial poly gate 170 may be removed in a selective etching manner.

Referring to FIG. 2G, in the interfacial film forming step g1, the gate electrode 340 and 370 including metal components may be formed in areas where the sacrificial layer 140 and the sacrificial poly gate 170 have been removed. An interfacial film including an oxide may be formed on an outer surface of each of the gate electrodes 340 and 370.

In some embodiments, after the sacrificial layer 140 and the sacrificial poly gate 170 are removed, and then, the gate electrode 340 and 370 are formed in areas where the sacrificial layer 140 and the sacrificial poly gate 170 have been removed, the source area 210 and the drain area 220 may be formed.

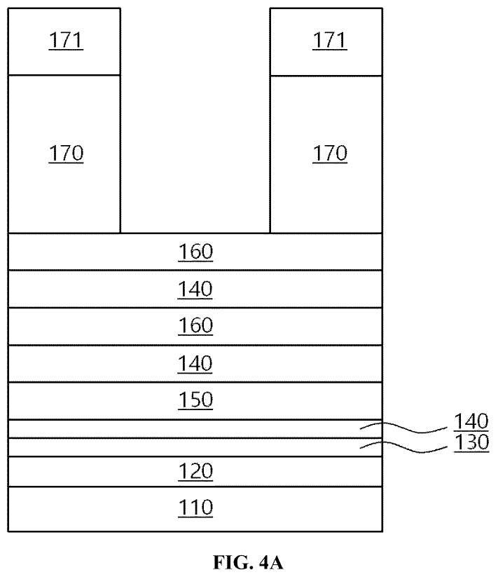

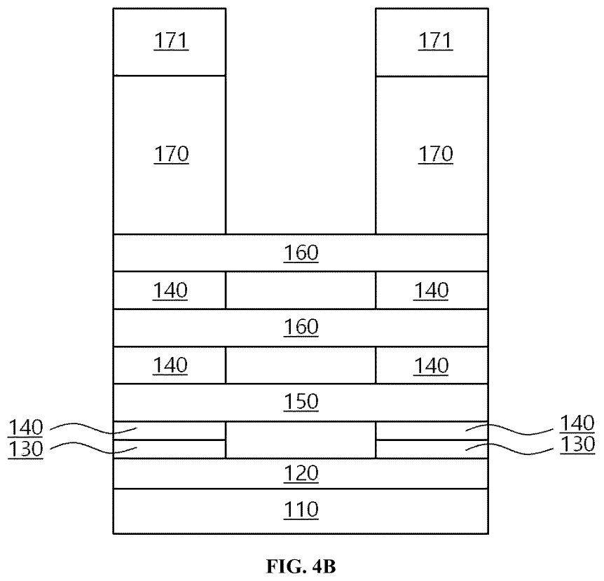

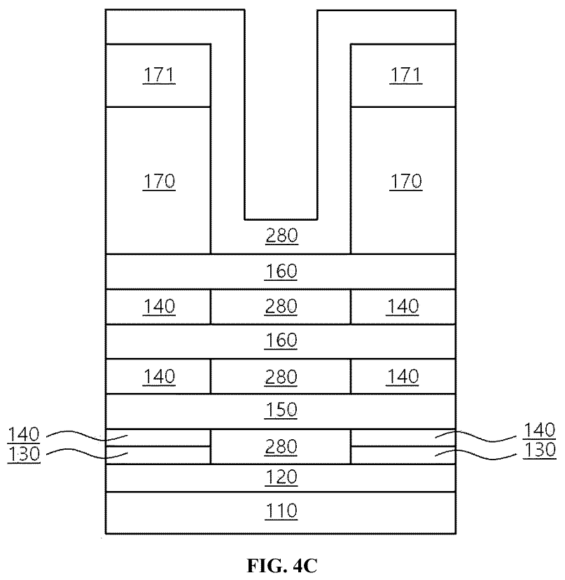

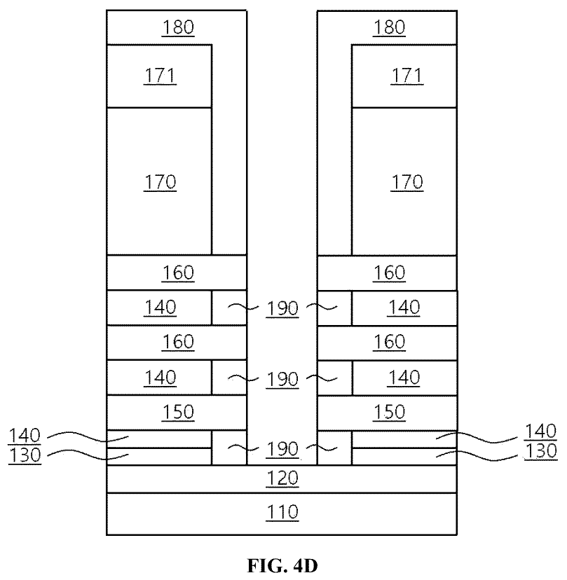

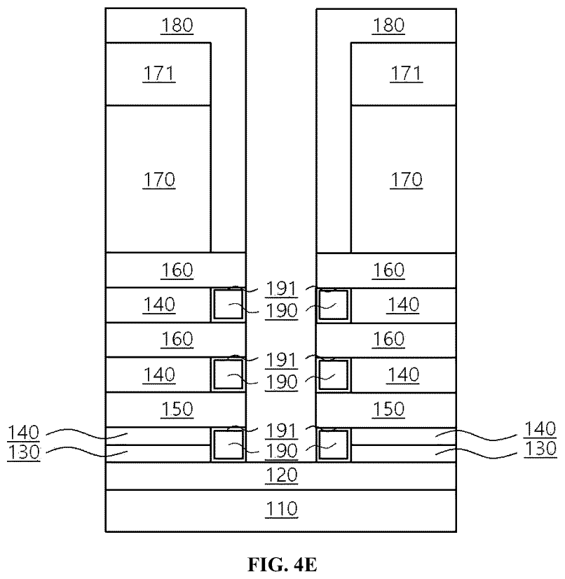

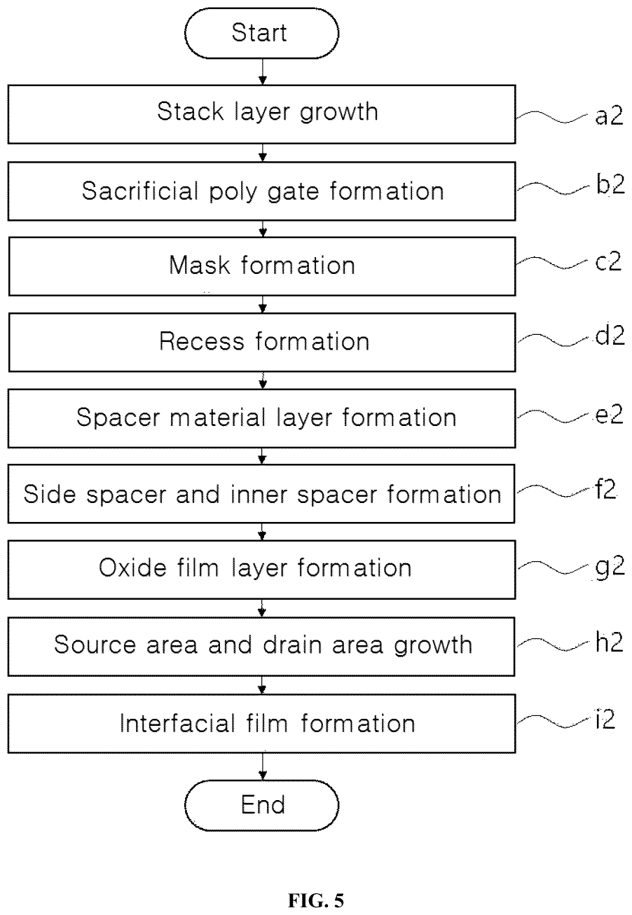

FIGS. 4A to 4E illustrate a process of fabricating a semiconductor device according to another embodiment. FIG. 5 is a flowchart for illustrating a method for manufacturing a semiconductor device according to still another embodiment.

Referring to FIG. 5, a method for manufacturing a semiconductor device according to still another embodiment may include a stack layer growth step a2, a sacrificial poly gate formation step b2, a mask formation step c2, a recess formation step d2, a spacer material layer formation step e2, a side spacer and an inner spacer formation step f2, and an oxide film layer formation step g2. Furthermore, the method for manufacturing the semiconductor device according to still another embodiment may further include a step h2 of growing a source area and a drain area, and an interfacial film forming step i2.

Referring to FIG. 4A, in the stack layer growing step a2, the base gate insulating film 130 may be stacked on the substrate 110 and 120. In some embodiments, the base gate insulating film 130 may be omitted. Subsequently, the stack layer, that is, the stack of the sacrificial layers 140 and the channel areas 150 and 160 may be disposed on the base gate insulating film 130 so as to be alternately stacked on top of each other. The sacrificial layer 140 and the channel areas 150 and 160 may be epitaxially formed.

In an embodiment, the sacrificial layer 140 may include SiGe and each of the channel areas 150 and 160 may include Si.

Referring to FIG. 4A, in the sacrificial poly gate forming step b2, the sacrificial poly gate 170 may be formed on the stack layer, that is, the stack of the sacrificial layers 140 and the channel areas 150 and 160. The sacrificial poly gates 170 may be formed to be spaced apart from each other in a horizontal direction. The sacrificial poly gate 170 may include silicon, for example, polysilicon.

Referring to FIG. 4A, in the mask forming step c2, a mask 171 may be formed on the sacrificial poly gate 170.

Referring to FIG. 4B, in the recess forming step d2, a recess may be formed by selectively removing a portion of each of the sacrificial layer 140 and the base gate insulating film 130. In the recess forming operation d2, the portion of each of the sacrificial layer 140 and the base gate insulating film 130 may be removed in a wet etching or dry etching manner, and may be removed in a selective etching manner.

Each of the sacrificial layer 140 and the base gate insulating film 130 may have a relatively higher selective etching rate with respect to the channel areas 150 and 160. Accordingly, when the sacrificial layer 140 and the base gate insulating film 130 are removed, the channel areas 150 and 160 may not be removed.

When the stacking process of the base gate insulating film 130 is omitted in the stack layer growing step a2, only a portion of the sacrificial layer 140 may be selectively removed in the recess forming step d2.

Referring to FIG. 4C, in the step e2 of forming of the spacer material layer, a spacer material layer 280 may be formed in the recess formed in the recess formation step d2 and on a side surface of the sacrificial poly gate 170. In the step e2 of forming of the spacer material layer, the sacrificial poly gate 170 may be used as a support structure and a mask. In an embodiment, the spacer material layer 280 may be formed in an atomic layer deposition (ALD) manner. The spacer material layer 280 may include a low dielectric material (or a low-k material).

Referring to FIG. 4D, in the step f2 of forming the side spacer and the inner spacer, the side spacer 180 and the inner spacer 190 may be formed by etching a portion of each of the channel areas 150 and 160 and a portion of the spacer material layer 280. In the step f2 of forming the side spacer and the inner spacer, the side spacer 180 and the inner spacer 190 may be simultaneously formed.

Referring to FIG. 4E, in the step g2 of forming of the oxide film layer, heat treatment may be performed on the inner spacer 190.

More specifically, in the step g2 of formation of the oxide film layer, the heat treatment may be performed on the inner spacer 190 in a chamber having an internal pressure set to a predetermined process pressure and having an internal temperature set to a predetermined process temperature. In an embodiment, the predetermined process pressure may be determined as a value within 2 atm to 100 atm. In one embodiment, the predetermined process temperature may be determined as value in a range of 200° C. to 600° C.

When the heat treatment is performed in the oxide film layer forming step g2, the atmosphere gas may be supplied into the chamber. In one embodiment, the atmosphere gas may be O₂ or H₂O. In one embodiment, a concentration of the atmosphere gas in the chamber may be 100%.

In an embodiment, the heat treatment performed in the formation step g2 of the oxide film layer may be performed in any one environment among wet, dry, or supercritical environment.

In some embodiments, the heat treatment may be performed on the side spacer 180 in the formation step g2 of the oxide film layer. Accordingly, the oxide film layer may be formed on the outer surface of the side spacer 180.

Although not shown, in the growth step h2 of the source area and the drain area, the source area 210 and the drain area 220 may be formed on both opposing sides of the stack layer, that is, the stack of the sacrificial layers 140 and the channel areas 150 and 160, respectively. In addition, in the growth step h2 of the source area and the drain area, each of the sacrificial layer 140 and the sacrificial poly gate 170 may be removed in the selective etching manner.

Although not shown, in the interfacial film forming step i2, the gate electrodes 340 and 370 including metal components may be formed in areas where the sacrificial layer 140 and the sacrificial poly gate 170 have been removed. The interfacial film including an oxide may be formed on an outer surface of each of the gate electrodes 340 and 370.

In some embodiments, after the sacrificial layer 140 and the sacrificial poly gate 170 are removed, and then, the gate electrode 340 and 370 are formed in areas where the sacrificial layer 140 and the sacrificial poly gate 170 have been removed, the source area 210 and the drain area 220 may be formed.

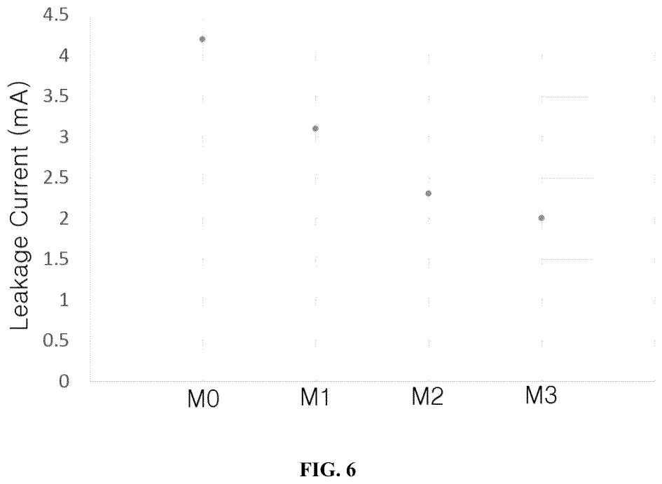

FIG. 6 is a graph illustrating a leakage current value measured when a voltage is applied to each of a semiconductor device manufactured according to the related art and a semiconductor device manufactured according to embodiments of the present disclosure.

In FIG. 6, M0 denotes a semiconductor device fabricated according to the related art, and each of M1 to M3 denotes a semiconductor device fabricated according to an embodiment of the present disclosure.

M0 refers to a semiconductor device that is manufactured in the same process as that of an embodiment of the present disclosure, except that the heat treatment is not performed on the inner spacer.

M1 refers to a semiconductor device that is manufactured in the same process as that of one embodiment of the present disclosure, and in which the heat treatment is performed on the inner spacer in a chamber in which a process temperature is set to 400° C. and a process pressure is set to 2 atm.

M2 refers to a semiconductor device that is manufactured in the same process as that of one embodiment of the present disclosure, and in which the heat treatment is performed on the inner spacer in a chamber in which a process temperature is set to 400° C. and a process pressure is set to 5 atm.

M3 refers to a semiconductor device that is manufactured in the same process as that of one embodiment of the present disclosure, and in which the heat treatment is performed on the inner spacer in a chamber in which a process temperature is set to 400° C. and a process pressure is set to 10 atm.

As shown in FIG. 6, the magnitude of the leakage current of each of the semiconductor devices M1 to M3 in which the heat treatment has been performed on the inner spacer according to an embodiment is smaller than the magnitude of the leakage current of the semiconductor device M0 in which the heat treatment is not performed on the inner spacer. In particular, it is identified that the magnitude of the leakage current of each of the semiconductor devices M1 to M3 in which the heat treatment has been performed on the inner spacer according to an embodiment is maintained at 3.5 MPa or lower. Therefore, when the heat treatment is performed on the inner spacer, the electrical characteristics of the semiconductor device may be improved.

Although the present disclosure has been described with reference to the accompanying drawings as described above, the present disclosure is not limited to the embodiments disclosed in the present disclosure and the drawings, and various modifications may be made thereto by a person skilled in the art. In addition, although an effect according to a configuration of the present disclosure is not explicitly described in describing the embodiments of the present disclosure above, a predictable effect from the configuration should also be recognized.

What is claimed is:

1. A method for manufacturing a semiconductor device, the method comprising:
growing a stack layer on a substrate, wherein the stack layer includes sacrificial layers and channel areas stacked alternately on top of each other;
forming a sacrificial poly gate on the stack layer;
forming an inner spacer and a side spacer on a side surface of the sacrificial layer and a side surface of the sacrificial poly gate, respectively; and
performing heat treatment on the inner spacer or the side spacer in a chamber having a pressure set to a predetermined process pressure and a temperature set to a predetermined process temperature.

2. The method of claim 1, wherein the predetermined process pressure is set to a value in a range of 2 atm to 100 atm.

3. The method of claim 1, wherein the predetermined process temperature is set to a value in a range of 200° C. to 600° C.

4. The method of claim 1, wherein an atmosphere gas is provided into the chamber, wherein the atmosphere gas includes O₂ or H₂O.

5. The method of claim 4, wherein the atmosphere gas has a concentration of 100%.

6. The method of claim 1, wherein the heat treatment is performed in a wet, dry or supercritical environment.

7. The method of claim 1, wherein the forming of the inner spacer and the side spacer includes forming the side spacer on the stack layer.

8. The method of claim 1, wherein the forming of the inner spacer and the side spacer includes:
removing a portion of each of the sacrificial layers to form a side recess; and
forming the inner spacer in the side recess.

9. The method of claim 1, wherein the forming of the inner spacer and the side spacer includes:
removing a portion of each of the sacrificial layers to form a recess;
forming a spacer material layer in the recess and on a side surface of the sacrificial poly gate; and
removing a portion of the channel area and a portion of the spacer material layer to form the inner spacer and the side spacer.

10. The method of claim 1, further comprising:
forming a source area and a drain area;
removing the sacrificial layer and the sacrificial poly gate; and
forming a gate electrode.

11. The method of claim 1, further comprising:
removing the sacrificial layer and the sacrificial poly gate;
forming a gate electrode; and
forming a source area and a drain area.

12. A semiconductor device comprising:
a substrate;
a channel area including a plurality of nanosheets stacked on the substrate;
a gate electrode disposed so as to contact at least one surface of the channel area;
a source area and a drain area disposed on both opposing sides of the channel area, respectively;
a side spacer disposed on a side surface of the gate electrode; and
an inner spacer disposed on a side surface of the gate electrode,
wherein a heat treatment is performed on the side spacer or the inner spacer in a chamber having a pressure set to a predetermined process pressure and a temperature set to a predetermined process temperature such that an oxide film layer is formed on an outer surface of the side spacer or the inner spacer.

13. The semiconductor device of claim 12, wherein the predetermined process pressure is set to a value in a range of 2 atm to 100 atm.

14. The semiconductor device of claim 12, wherein the predetermined process temperature is set to a value in a range of 200 C. to 600° C.

15. The semiconductor device of claim 12, wherein an atmosphere gas is provided into the chamber,
wherein the atmosphere gas includes O₂ or H₂O.

16. The semiconductor device of claim 15, wherein the atmosphere gas has a concentration of 100%.

17. The semiconductor device of claim 12, wherein the heat treatment is performed in a wet, dry or supercritical environment.
